(19) United States
(12) Patent Application Publication
(10) Pub. No.: US 2025/0176304 A1
(43) Pub. Date: May 29, 2025

(54) METHODS OF TREATMENT & MANUFACTURE OF A SOLAR CELL

(71) Applicant: REC Solar PTE. Ltd., Singapore (SG)

(72) Inventors: Yong Soon MOK, Singapore (SG); Yong Xin CHOO, Singapore (SG); Shu Yunn CHONG, Singapore (SG); Yu Hao WU, Singapore (SG)

(73) Assignee: REC Solar PTE. Ltd., Singapore (SG)

(21) Appl. No.: 18/725,624

(22) PCT Filed: Dec. 9, 2022
(86) PCT No.: PCT/EP2022/085156

§ 371 Date: Jun. 28, 2024

(30) Foreign Application Priority Data
Dec. 29, 2021 (GB) 2119066.5

(51) Int. Cl. H10F 71/00; H10F 10/166; H10F 71/10

(52) U.S. Cl. CPC H10F 71/135; H10F 10/166; H10F 71/103; H10F 71/134; H10F 71/137; H10F 71/138

(57) ABSTRACT

A method of treatment of at least one cut solar cell, the method including steps of: providing the at least one solar cell, said cell having previously been subjected to a cutting process; and performing a carrier injection treatment on at least a cut edge of the cell.

### CROSS-REFERENCE TO RELATED APPLICATIONS

This application is a U.S. National Phase Patent Application based on International Patent Application No. PCT/EP2022/085156, filed Dec. 9, 2022; which claims priority to GB Patent Application No. 2119066.5, filed Dec. 29, 2021. The above referenced applications are incorporated herein by reference in their entirety as if fully set forth herein.

### FIELD OF THE INVENTION

The present invention relates to methods of treatment of a solar cell, methods of manufacture of a solar cell, and to a solar cell treated or manufactured according to said methods.

### BACKGROUND

Solar cells (also referred to as photovoltaic cells) are used for the provision of electrical energy from sunlight by means of the photovoltaic effect. Two of the main drivers for technical development of existing solar cell technologies are (i) a desire to increase the efficiency of the cells; and (ii) a desire to decrease the fabrication cost of the cells.

One of the major electronic loss mechanisms in solar cells is carrier recombination within the cell. In particular, carrier recombination at the electrical contacts as a result of direct metal/silicon interfaces featuring a high density of recombination-active localized states. This high surface-state density increases the carrier recombination rate at the interface. The use of passivating-contact technologies such as in silicon heterojunction (HJT) solar cells has been found to reduce or minimise these losses. A HJT solar cell typically features a symmetrical structure comprising a crystalline silicon wafer, c-Si, (sometimes referred to as the ‘substrate’) surrounded by front and back layers of amorphous silicon, generally hydrogenated amorphous silicon (a-Si:H). The front and back a-Si layers may be combination intrinsic/doped layers (the intrinsic portion of the layer constituting a passivation layer, and the doped portion of the layer constituting a collector layer (e.g. electron or hole collector layer)). Transparent conducting oxide (TCO) layers are typically disposed on the front and back a-Si layers, which both act as anti-reflection coatings, but also allow for charge transport to metal electrodes which are disposed on the front and back TCO layers. The terms “front” and “forward” are used herein to refer to a direction towards a light source (e.g. the sun) in use and orthogonal to a front face of the solar cell, and the terms “back”, “rear” and “rearwardly” are intended to refer to a direction that is opposite to the front/forward direction.

Some work has been done to increase solar cell efficiency of HJT solar cells further. In the article Kobayashi et al., “Increasing the efficiency of silicon heterojunction solar cells and modules by light soaking”, Solar Energy Materials and Solar Cells, Volume 173, 2017, Pages 43-49, ISSN 0927-0248, it is proposed that light exposure of silicon heterojunction solar cells can increase their operating voltage, and thus their conversion efficiencies during light exposure. The authors attribute this performance improvement to improved passivation of the hetero-interface (c-Si/a-Si).

US2015013758A1 discloses a process for treating n-type photovoltaic cells containing no boron, including steps of illuminating the n-type heterojunction cell during a heat treatment carried out at a temperature between 2° and 200° C.

WO2020221399A1 discloses a method for stabilizing solar cells in which the stabilization step involves heating the solar cell to temperatures over 200° C. and an illumination from a light source, wherein the light source emits light in a wavelength range <2500 nm and wherein a light dose emitted by the light source in this wavelength range is more than 8000 Ws/m2, and wherein the stabilization step includes a temperature treatment with a maximum 10 seconds long temperature peak with temperatures above 350° C.

All of the above work focuses on improvements in efficiency of full solar cells due to reduction of intrinsic defects in the HJT solar cell, for example due to bulk defects or impurities in the c-Si layer, or at the c-Si/a-Si interface.

The present invention has been devised in light of the above considerations.

### SUMMARY OF THE INVENTION

Whilst existing literature focuses on improvement of efficiency of full solar cells due to reduction of intrinsic defects in the solar cell, the present inventors have realised that for solar cells which undergo a cutting process (e.g. in the formation of half cut cells), this cutting process can result in an increased defect density on the surface and edge of the half cells after cutting. The use of half-cut cells can offer advantages over full cells, such as improved performance and durability. It would be desirable to reduce or minimise the effects of defects introduced during the cutting process, which can otherwise reduce the open voltage and fill factor of the final solar module incorporating said cells.

The present inventors have found that provision of a post-cutting treatment to the cut cells can improve performance of those cells, in comparison to cut cells which do not undergo such a treatment.

Accordingly, in a first aspect, the present invention provides a method of treatment of at least one cut solar cell, the method including steps of:
providing the at least one solar cell, said cell having previously been subjected to a cutting process; and
performing a carrier injection treatment on at least a cut edge of the cell.

Specifically, the present inventors have found that by performing a carrier injection treatment on at least a cut edge of a cut solar cell, one or more of the photoluminescent intensity, the module V_{oc}, and/or the module Fill Factor % (FF %) may be advantageously improved in comparison to cells which have not undergone such treatment. Furthermore, the present inventors have found surprisingly that the improvement in one or more of these performance indicators may be improved by a greater degree than the comparative improvement seen when the same treatment is applied to a cell that has not previously been subjected to a cutting process.

The present inventors consider that this method may be applicable to a number of different types of solar cell—for example, the solar cell may be a heterojunction solar cell (HJT solar cell). Alternatively, it may be a PERC solar cell, such as a P-type Mono PERC cell.

In preferred embodiments, the solar cell is a heterojunction solar cell. As discussed above, a HJT solar cell typically features a symmetrical structure comprising a crystalline silicon wafer, c-Si, surrounded by front and back layers of amorphous silicon (a-Si), generally hydrogenated amorphous silicon (a-Si:H). Without wishing to be bound by theory, the present inventors hypothesise that by applying a carrier injection treatment to the cut cell, the injected carriers may improve the passivation at the a-Si/c-Si interface, both within the bulk cell, and at the cut edge, e.g. as a result of liberated energy from recombination of the injected carriers aiding in nearby interface-state healing. Alternatively or additionally, the carrier injection treatment may cause an increase in mobility of hydrogen gas that is ‘trapped’ during the formation of the amorphous layers. This increased mobility may cause hydrogen to travel to defect sites in the cell, passivating them and hence reducing the overall defect density.

The carrier injection treatment may comprise a light-based carrier injection treatment. Alternatively, the carrier injection treatment may comprise a charge-based carrier injection treatment. A light based carrier injection treatment may include, for example, a halogen lamp treatment, an LED lamp treatment and/or a laser treatment. A charge-based carrier injection treatment may include, for example, an electron injection treatment.

The carrier injection treatment may therefore include at least one treatment selected from:
a halogen lamp treatment,
an LED lamp treatment,
a laser treatment,
and/or an electron injection treatment.

In some methods, the carrier injection treatment consists of one type of treatment selected from these four types of treatment. In other methods, two or more of these types of carrier injection treatment may be used in combination, e.g. subsequently or simultaneously. However, as the benefits from applying different types of treatment are generally not additive, it may be preferred to only use a single type of treatment from the above list, to reduce complexity of the treatment.

The carrier injection treatment may comprise a single continuous carrier injection treatment step which is performed using predetermined treatment parameters (selected based on the type of carrier injection treatment performed) for a predetermined amount of time.

Alternatively, the carrier injection treatment may comprise a plurality of discrete carrier injection treatment sub-steps. In other words, the carrier injection treatment may be performed over a plurality of discrete predefined time periods. The number of discrete carrier injection treatment steps is not particularly limited: the carrier injection treatment may comprise two or more, three or more, four or more or five or more sub-steps. Performing a carrier injection treatment comprising a plurality of discrete carrier injection treatment sub-steps can give an advantage of better through-put of cells to be treated. In other words, such method may have improved industrial efficiency.

The total carrier injection treatment time may vary depending on the type of carrier injection treatment performed. For example, light-based carrier injection treatment may require shorter treatment times than charge-based carrier injection treatments, because they may be comparatively higher energy intensity processes than charge based treatment methods.

The total carrier injection time may be in a range of from 5 seconds to 1 hour. It is preferred that the total carrier injection treatment time is not less than 5 seconds, as a minimum exposure time of 5 seconds or more may be required to observe any significant improvement in efficiency of the cells. It is preferred that the total carrier injection treatment time is not more than 1 hour, because an increased length of treatment increases the thermal budget (total amount of thermal energy transferred during a given elevated temperature operation). Conducting a treatment of more than 1 hour may result in degradation of the cell and hence its efficiency. Furthermore, providing long treatments may also lower the throughput of cell it is possible to treat in a given time period, thereby lowering process efficiency.

Where the carrier injection treatment comprises a plurality of discrete carrier injection treatment sub-steps, the treatment time during each of these sub-steps may each be from 5 seconds to 800 seconds. For light-based carrier injection treatments, the treatment time during each sub-step may be e.g. from 5 to 120 seconds, more preferably from 10 to 60 seconds. For charge-based carrier injection treatments, the treatment time during each sub-step may be e.g. from 100 to 800 seconds, more preferably from 200 to 400 seconds. In this case, the total carrier injection treatment time can be calculated as the cumulative total time of performance of all the carrier injection treatment sub-steps: for example, where four discrete treatment steps are performed, with each being performed for 300 seconds, the total treatment time will be 1200 seconds (20 minutes).

The carrier injection treatment may be performed such that the temperature of the cell during treatment does not exceed a temperature of greater than 300° C., greater than 250° C., greater than 200° C., greater than 150° C., or greater than 100° C. In some arrangements, the temperature of the cell during treatment may be in a range of from 100° C. to 300° C. If the temperature of the cell during treatment is less than 100° C., hydrogen passivation at the a-Si/c-Si interface may not be as effective, as lower temperatures may decrease the concentration of hydrogen in minority species. If the temperature of the cell during treatment is greater than 300° C., these higher temperatures may cause dissociation of Si—H bonds which were previously passivated, thereby leading to a reduction in cell performance.

The optimal temperature of the cell during the carrier injection treatment may depend on the type of carrier injection.

For light based carrier injection treatments, the temperature of the cell may rise from about room temperature to peak at a temperature of 200+° C. On removal of illumination, the cell may rapidly cool back to room temperature (e.g. within minutes or seconds)-in particular, where the light based carrier injection is performed on a single cell, the single cell may have a relatively large effective surface area per unit volume, thereby allowing for rapid heat transfer away from the cell on termination of the treatment.

In comparison, for charge based carrier injection treatments, slower rates of heating and cooling may be observed during and after treatment. In particular, this may be the case where a plurality of cells are stacked for simultaneous treatment, as discussed in further detail below, as the effective surface area per unit volume for heat transfer may be relatively small. For example, when a charge-based carrier injection treatment is performed, the temperature of the cell may rise from room temperature to be maintained at around ˜130° C. for the duration of treatment. When treatment is stopped, it may take 20 minutes or so to cool back down to room temperature. As the rate of cooling for charge based carrier injection treatments may be slower than for light-based treatments, the peak temperature during the carrier injection treatment may be selected to be comparatively lower than for light-based treatments, to avoid damage to the cell caused by prolonged exposure to high temperatures.

The treatment temperature may remain substantially constant throughout the carrier injection treatment. Alternatively, the treatment temperature may vary throughout the carrier injection treatment. Where the carrier injection treatment comprises a plurality of discrete carrier injection treatment sub-steps, the treatment temperature may be substantially the same across all sub-steps, or may vary between sub-steps.

One or more further treatment parameters of the carrier injection treatment including but not limited to: applied current, power, and/or light intensity of the treatment (as applicable) may remain substantially constant throughout the carrier injection treatment. Alternatively, one or more of such treatment parameters may be varied throughout the carrier injection treatment. In particular, where the carrier injection treatment is performed as a plurality of discrete carrier injection treatment sub-steps, the applied current, power, and/or light intensity (as applicable) may be varied between the discrete carrier injection treatment sub-steps.

Selection of appropriate treatment parameters (applied current, power, light intensity, etc.) for each type of carrier injection treatment set out above (halogen lamp treatment, LED lamp treatment, electron injection treatment, and/or laser treatment) is discussed in greater detail below, alongside discussion of further optional features relating to each type of carrier injection treatment.

Where the carrier injection treatment includes a charge-based carrier injection treatment, such as an electron injection treatment, the carrier injection treatment may comprise exposing at least the cut edge of the cell to electrons injected by the treatment.

In some charge-based carrier injection methods, a voltage may be applied to one or more cells, causing a current to flow through. In one suitable arrangement, a voltage may be applied to one or more cells by arranging the cell in electrical connection with two electrodes of a process unit to form a complete circuit, with a power supply unit of the process unit then applying a voltage between the electrodes, causing current to flow through the cell. The voltage applied may be a fixed, or approximately fixed, voltage.

The charge-based carrier injection treatment may be performed at any suitable predetermined applied current. In some arrangements, the treatment may be performed at an applied current of from 4 to 10 A. In preferred arrangements, the treatment is performed at an applied current of from 5 to 7 A, for example at about 4.3 A, about 5 A, about 5.5 A, about 5.8 A, about 6 A or about 6.7 A. The applied current may be same throughout the treatment. Alternatively, the applied current may be varied through the treatment. For example, where the treatment is performed as a series of sub-steps, the applied current during a first sub-step may be different to the applied current during a second sub-step.

In some preferred methods, the charge-based carrier injection treatment is performed as a series of four sub-steps, each sub-step being performed for a time of 300 seconds, for a total treatment time of 1200 seconds. The applied current during each of the four sub-steps may be e.g. 4.3/6/6/6 A, 5.5/5.8/5.8/5.8 A, 6/6.7/6.7/6.7 A, or 5/5/5/5 A.

During the treatment process, as current flows through the cell(s), power is dissipated, and the resulting heat may cause the temperature of the cell(s) to increase. The cell temperature of the one or more cells being treated may be monitored, e.g. by one or more temperature sensors. Any suitable temperature sensor may be used; however a particularly preferred type of temperature sensor is an infrared sensor, which allows non-invasive temperature measurement. The temperature to be maintained in the cell (the ‘setpoint temperature’) may then be set as a parameter of the treatment. In one arrangement, when the temperature sensor detects that the cell temperature exceeds the setpoint temperature, a feedback loop may trigger one or more actions to be performed in order to maintain the cell temperature at the setpoint temperature. For example, when the temperature sensor detects that the cell temperature exceeds the setpoint temperature a feedback loop may trigger a cooling mechanism to be activated to thereby reduce the temperature of the cell to maintain it at the desired setpoint temperature. For example, in one arrangement, a compressed dry air (CDA) supply may be triggered to be turned on, to thereby maintain the temperature of the cell(s) at the setpoint temperature by applying compressed dry air.

In one particularly preferred arrangement, a plurality of cells may be treated simultaneously. In such an arrangement, the plurality of cells may be stacked together in a coinstack and loaded in a magazine. The cells may be stacked in series, with the negative side of one cell in contact with positive side of an adjacent cell, vice versa. To perform the charge-based carrier injection treatment, the cell stack may be sandwiched between two metal plates in the magazine and arranged to be disposed between two electrodes of a process unit to form a complete circuit, with a power supply unit in the process unit then applying a voltage between the electrodes, causing current to flow through the plurality of cells.

Where the carrier injection treatment includes an LED lamp treatment, the LED lamp treatment may comprise a step of exposing at least the cut edge of the cell to light emitted from an LED lamp at a light intensity of from 80 to 180 suns, wherein 1 sun corresponds to standard illumination at AM1.5. The AM1.5 Global spectrum is designed for flat plate modules and has an integrated power of 1000 W/m² (100 mW/cm²) as defined in ASTM G-173-03 (International standard ISO 9845-1, 1992). The light intensity may in some cases be 90 suns or more, 100 suns or more, 110 suns or more, 120 suns or more, 130 suns or more, 140 suns or more, or 150 suns or more. The light intensity may in some cases be 180 suns or less, 170 suns or less, 160 suns or less or 150 suns or less.

The distance between the cell(s) being treated and the illuminating light source may be in a range of from 5 to 40 cm. For example, the distance between the cell(s) being treated and the illuminating light source may be 5 cm or more, 10 cm or more, 15 cm or more, or 20 cm or more. The distance between the cell(s) being treated and the illuminating light source may be 40 cm or less, 35 cm or less, 30 cm or less, or 25 cm or less.

In one suitable method, the cell(s) may be conveyed into a soaking chamber comprising one or more LED lamp panels configured for emission of white LED light (full spectrum-equivalent to AM1.5 Global spectrum). The length of treatment time (also sometimes referred to as the exposure time or the processing time) may be determined by the conveyor speed as well as the length of the soaking chamber.

During the soaking process, the temperature of the cells may increase to a temperature of 200° C. or higher. Preferably, the cells are not heated to a temperature of greater than 300° C., for the reasons set out above. In a similar manner as described above in relation to charge-based carrier injection processes, the cell temperature of the one or more cells being treated may be monitored, e.g. by one or more temperature sensors during the treatment, and the temperature to be maintained in the cell (the ‘setpoint temperature’) may be set as a parameter of the treatment and maintained e.g. by suitable action being performed to maintain the cell temperature at the setpoint temperature, when the temperature sensor detects that the cell temperature exceeds the setpoint temperature.

Where the carrier injection treatment includes a halogen lamp treatment, the halogen lamp treatment may comprise a step of exposing at least the cut edge of the cell to light emitted from a halogen lamp having a luminous flux (lm) in a range of from 10000 lm to 60000 lm, more preferably in a range of from about 20000 lm to about 30000 lm, more preferably in a range of from about 22000 lm to about 24000 lm.

One convenient option is a commercially-available 1000W halogen lamp having a luminous flux of about 23400 lm. This has been found to provide suitable performance enhancement in the cells upon treatment. However, other commercially-available halogen lamps are available, which may have a lumen/power ratio of from 1 lumen per watt to 637 lumen per watt. These other commercially-available lamps may be suitable for performing a carrier injection treatment according to the present invention.

The distance between the cell(s) being treated and the illuminating light source may be in a range of from 5 to 40 cm. For example, the distance between the cell(s) being treated and the illuminating light source may be 5 cm or more, 10 cm or more, 15 cm or more, or 20 cm or more. The distance between the cell(s) being treated and the illuminating light source may be 40 cm or less, 35 cm or less, 30 cm or less, or 25 cm or less.

In one suitable method, the cell(s) may be conveyed into a soaking chamber comprising one or more halogen lamp panels configured for emission of white light (full spectrum-equivalent to AM1.5 Global spectrum). The length of treatment time (also sometimes referred to as the exposure time or the processing time) may be determined by the conveyor speed as well as the length of the soaking chamber.

During the soaking process, the temperature of the cells may increase to 200° C. or higher. Preferably, the cells are not heated to a temperature of greater than 300° C., for the reasons set out above. In a similar manner as described above in relation to charge-based carrier injection processes, the cell temperature of the one or more cells being treated may be monitored, e.g. by one or more temperature sensors during the treatment, and the temperature to be maintained in the cell (the ‘setpoint temperature’) may be set as a parameter of the treatment and maintained e.g. by suitable action being performed to maintain the cell temperature at the setpoint temperature, when the temperature sensor detects that the cell temperature exceeds the setpoint temperature.

Where the carrier injection treatment includes laser treatment, the laser treatment may comprise a step of exposing at least the cut edge of the cell to light emitted from a laser having a specified predetermined wavelength and power.

The use of a laser-based carrier injection treatment may be preferred over the use of other light-based carrier injection treatments, because the illumination uniformity may be significantly improved, and energy transfer to the cell being treated more efficient and effective.

The laser may have a wavelength in infrared range. In other words, the laser may have a wavelength in the range of from about 700 nm to about 1 mm. More preferably, the wavelength may be in a range of from 780 nm to 1300 nm, more preferably 780 nm to 1000 nm. Use of a laser having a wavelength of about 1000 nm may be particularly preferred.

The laser may have a power in a range of from 1000-4000 W, more preferably in a range of from 2000 W to 3000 W. In some cases, the laser may have a power of about 2800 W.

One example of a laser that has been found to be suitable for use in performing such treatments is a K1-LIA-Y9000 laser by Dr Laser.

The distance between the cell(s) being treated and the illuminating light source may be in a range of from 10 to 20 cm. For example, the distance between the cell(s) being treated and the illuminating light source may be 10 cm or more, or 15 cm or more. The distance between the cell(s) being treated and the illuminating light source may be 20 cm or less, or 15 cm or less.

During the laser-based carrier injection treatment, the cell(s) may remain substantially static.

As the laser light is applied to the cells, the temperature of the cells may increase to a temperature in a range of from about 150° C. to 250° C. Preferably, the cells are not heated to a temperature of greater than 300° C., for the reasons set out above. In a similar manner as described above in relation to charge-based carrier injection processes, the cell temperature of the one or more cells being treated may be monitored, e.g. by one or more temperature sensors during the treatment, and the temperature to be maintained in the cell (the ‘setpoint temperature’) may be set as a parameter of the treatment and maintained e.g. by suitable action being performed to maintain the cell temperature at the setpoint temperature, when the temperature sensor detects that the cell temperature exceeds the setpoint temperature.

Methods according to the present invention may include the treatment of a single cut solar cell which has previously been subjected to a cutting process. However, in preferred methods, a plurality of cut solar cell cells are treated simultaneously. The number of cells treated simultaneously is not particularly limited, other than by practical considerations of the treatment apparatus available. The method may therefore include treating 2 or more, 5 or more, 10 or more, 20 or more, 30 or more, 40 or more, 50 or more, 100 or more, 200 or more 300 or more or 400 or more cut solar cell cells simultaneously. Treating multiple solar cells in a single method of treatment can dramatically improve the efficiency of the treatment process, resulting in lower manufacturing cost for the treated solar cells. However, it may be preferable to limit the total number of cells to be treated to no more than 400 cells at any one time, to avoid overheating of the cells during the treatment process.

To treat multiple cells simultaneously, the plurality of cut cells may be stacked, and the carrier injection treatment performed simultaneously on the stacked cells. The cells may be stacked such that the cut edges of the cells are substantially aligned with one another. In this way, the carrier injection treatment can more easily be performed on a plurality of the cut edges simultaneously. Whilst it is preferable for the cut edges of the plurality of cells to be substantially aligned, a small amount of misalignment may be tolerable.

Accordingly, the method may include steps of:
providing a plurality of solar cells, each of said cells having previously been subjected to a cutting process;
stacking said plurality of solar cells such that a cut edge of each of the cells is substantially aligned with a cut edge of the rest of the plurality of solar cells; and
simultaneously performing a carrier injection treatment on the cut edges of the plurality of solar cells.

The method of treatment may be performed as a stand-alone method, e.g. on commercially obtained cells.

Alternatively, the method of treatment may form part of a method of manufacture of a heterojunction solar cell. In preferred embodiments, the solar cells are heterojunction solar cells.

Accordingly, in a second aspect, the present invention provides a method of manufacture of a solar cell, the method including steps of:
(a) providing a crystalline silicon (c-Si) wafer;
(b) depositing front and back amorphous silicon (a-Si) layers on a front side and a back side of the crystalline silicon wafer respectively;
(c) depositing front and back transparent conducting oxide (TCO) layers on the front and back amorphous silicon (a-Si) layers respectively;
(d) performing metallization to form one or more metal electrodes on the front and/or back TCO layers;
(e) cutting the solar cell (or part-manufactured solar cell); and
(f) performing a carrier injection treatment on at least a cut edge of the cell;
wherein the step (e) of cutting the solar cell is performed at any time from after step (a) to after step (d), and wherein step (f) of performing a carrier injection treatment on at least a cut edge of the cell is performed at any time after both of steps (b) and (e) have been performed.

The step (a) of providing a crystalline silicon (c-Si) wafer may include obtaining (e.g. by purchasing) a crystalline silicon (c-Si) wafer from a commercial source. Alternatively, it may include manufacturing crystalline silicon (c-Si) wafer in any suitable manner, for example by growing a single crystal silicon ingot or boule via the Czochralski (CZ) method, and cutting this into wafers in a manner well-known in the art.

The c-Si wafer may also be referred to herein as the solar cell substrate. The substrate may be an n-type semiconductor, or it may be a p-type semiconductor. When the substrate is an n-type semiconductor, the semiconductor material may be configured to contain impurities of a group V element such as phosphor (P), arsenic (As), and antimony (Sb). When substrate is a p-type semiconductor material, it may contain impurities of a group III element such as boron (B), gallium (Ga), and indium (In). In preferred arrangements, the substrate comprises an n-type monocrystalline silicon wafer. n-type c-Si may exhibit longer lifetime characteristics when used as part of a heterojunction solar cell as compared with a p-type monocrystalline silicon wafer.

The method may include a step of texturing crystalline silicon (c-Si) wafer after step (a), for example between step (a) and step (b). Said texturing may form an uneven surface or a surface having uneven characteristics. Texturing of the c-Si wafer can reduce light reflectance and enhance light trapping at the solar cell surface, thus increasing the efficiency of the solar cell. Texturing may be performed in any conventional manner, for example by anisotropic wet chemical etching to form a pyramidal texture on a (100) silicon wafer surface by etching back to the (111) planes.

In some methods, the texturing step may comprise sub-steps of: cleaning the c-Si substrate of organic surface contamination; performing texturing by applying a mixture of KOH and additives to achieve the required reflectance; and cleaning the c-Si substrate to remove organic and metallic contaminations (if present) as well as surface oxide.

In some arrangements, each of the constituent layers of the solar cell (e.g. the substrate, hole-collector layer, electron-collector layer, passivation layer(s) and/or transparent-conductive layer) may be textured such that they have an uneven surface, or have uneven characteristics.

The amorphous silicon (a-Si) deposited in step (b) may be hydrogenated amorphous silicon (a-Si:H). The step (b) of depositing front and back amorphous silicon (a-Si) layers on a front side and a back side of the crystalline silicon wafer respectively may include sub-steps of:
(i) depositing a front and back intrinsic amorphous silicon (a-Si (i)) layer on a front side and a back side of the crystalline silicon wafer respectively; and
(ii) depositing a p- or n-doped amorphous silicon (a-Si (n), a-Si (p)) layer on each of the front and back intrinsic amorphous silicon (a-Si (i)) layers.

Where the amorphous silicon layer comprises hydrogenated amorphous silicon, these sub-steps may therefore include:
(i) depositing a front and back intrinsic hydrogenated amorphous silicon (a-Si:H (i)) layer on a front side and a back side of the crystalline silicon wafer respectively; and
(ii) depositing a p- or n-doped hydrogenated amorphous silicon (a-Si:H (n), a-Si:H (p)) layer on each of the front and back intrinsic hydrogenated amorphous silicon (a-Si:H (i)) layers.

In this way, the front and back intrinsic amorphous silicon (a-Si (i)) layers act as passivation layers, and the front and back p- or n-doped amorphous silicon (a-Si (n), a-Si (p)) layers act as collector layers (e.g. a hole-collector layer or an electron-collector layer). These may conventionally be referred to as “emitter” layers. One of these collector/emitter layers combines with the substrate to form a p-n junction. The other collector/emitter layer functions to collect charge carriers from the substrate.

During operation of the solar cell, a plurality of electron-hole pairs are produced by light incident on the substrate. When the substrate is n-type, the collector layer forming part of the p-n junction is p-type, the separated holes move to that collector layer, and the separate electrons move to the substrate. Accordingly, the holes become majority carriers in that collector layer. Also, the electrons become majority carriers in the substrate, and are subsequently collected by the other collector layer.

When the doped amorphous silicon is an n-type semiconductor, the semiconductor material may be configured to contain impurities of a group V element such as phosphor (P), arsenic (As), and antimony (Sb). When the doped amorphous silicon is a p-type semiconductor material, it may contain impurities of a group III element such as boron (B), gallium (Ga), and indium (In).

The step (b) of depositing front and back amorphous silicon (a-Si) layers on a front side and a back side of the crystalline silicon wafer respectively may be performed in any suitable manner. In preferred methods, this step is performed using plasma-enhanced chemical vapor deposition (PECVD). PECVD is a well established technique for deposition of a wide variety of films, and can be applied in a conventional manner to deposit the amorphous silicon (a-Si) layers. One example of a suitable method is a PECVD deposition process involving the flow of silane gas and hydrogen gas into the process chamber and utilization of plasma to form the amorphous silicon layers. Doping gases may be introduced in addition to silane and hydrogen gas as required to form the doped n/p layers.

It is preferred to deposit the rear n and p layers in separate process steps, but the front i/n layer together/sequentially. This may reduce the impact of phosphine contamination at the c-Si and a-Si:H (p) interface.

The step (c) of depositing front and back transparent conducting oxide (TCO) layers on the front and back amorphous silicon (a-Si) layers respectively may be performed using physical vapor deposition (PVD). PVD is a well established technique for deposition of a wide variety of films, and can be applied in a conventional manner to deposit the TCO layers. The PVD process may use rotary TCO targets-in a conventional manner for PVD processes, argon gas that is ionized that will bombard and sputter the TCO onto the passivated wafers while they are being transported on a supporting tray. This process can then be repeated for both sides of the passivated wafers.

The specific TCO material used to form the TCO layers is not particularly limited, although in preferred methods, the TCO layers may comprise indium tin oxide (ITO). The TCO layers may be textured to provide an anti-reflective surface. Where this is the case, the TCO layer can act as an anti-reflection layer which advantageously reduces the reflectance of light incident on the solar cell and increases selectivity of a predetermined wavelength band, thereby increasing the efficiency of the solar cell.

The step (d) of performing metallization to form one or more metal electrodes on the front and/or back TCO layers may be performed in any suitable manner conventionally known in the art. However, in preferred arrangements, the step (d) comprises sub-steps of:
applying a metallisation material to the front and/or back TCO layers; and
performing a heat treatment to form the one or more metal electrodes from the metallisation material.

The step of applying a metallization material may be performed using a printing process—for example, by screen printing. Use of a printing process to apply the metallization material may enable the formation of fine (i.e. narrow width and small depth) electrodes.

Where a heat treatment is performed to form the one or more metal electrodes from a metallisation material, the heat treatment may be performed at a temperature not greater than 250° C.—for example it may be performed at temperature in a range of from 180° C. to 200° C., e.g. at about 185° C., about 190° C. or about 195° C. Performing the heat treatment at temperatures lower than 250° C. can reduce or prevent degradation of the underlying amorphous silicon layer during the process. Performing the heat treatment at temperature of greater than 180° C. may be necessary to ensure complete or suitable formation of the metal electrodes from the metallisation material.

Where metal electrodes are located on a front face of the solar cell, they may be referred to as a ‘front electrode’. Where metal electrodes are located on a back face of the solar cell, they may be referred to as a ‘back electrode’.

The front and/or back electrodes may each comprise a plurality of finger electrodes which are arranged on the respective front and back surfaces of the solar cell. Each finger electrode may be configured with an axial length which is substantially greater than its width. Both the width and axial length of the finger electrode may be measured in perpendicular directions in the plane of the respective surface of the solar cell. The finger electrodes may extend in a transverse direction which is parallel with the width direction of the solar cell.

The finger electrodes within each of the pluralities of front and/or back finger electrodes may be spaced apart across the respective front and back surfaces of the solar cell to define transversely-extending spaces between the finger electrodes. The finger electrodes may be spaced apart in a longitudinal direction which is substantially parallel with the length direction of the solar cell. The finger electrodes in each plurality may be substantially parallel to one another. Accordingly, the plurality of back finger electrodes may form an array of parallel, longitudinally spaced (e.g. equally spaced) finger electrodes.

The front and/or back electrodes may comprise one or more further conductive elements (e.g. elongate busbars, or conductive wire portions), configured to form an electrical connection between the finger electrodes and an electrical circuit of a solar module incorporating the solar cell.

The step (e) of cutting the solar cell may be performed by a laser-based, or laser-assisted cutting process. For example, in some embodiments, the step of cutting the solar cell may include a step of scribing the cell with a laser, followed by mechanically splitting the cell along the scribed line. In other embodiments, the step of cutting the solar cell may include a step of scribing the cell with a laser and heating the cell along a line, followed by rapid cooling of the heated region by separate non-laser mechanism. In this process, the scribe creates a leading crack edge and the heating and rapid cooling creates stress in the wafer which propagates the crack and splits the cell.

Alternatively, any other suitable cutting process may be used (for example, an entirely mechanical cutting process). As set out above, the step (e) of cutting the solar cell may be performed at any time from after step (a) to after step (d), that is, it may be performed at any time before performing the carrier injection treatment. For example, cutting the cell, or cutting the part-manufactured cell comprising a layered structure, may be performed immediately after step (a) of providing a crystalline silicon (c-Si) wafer. Alternatively, it may be performed immediately after a step of texturing the provided c-Si wafer. Alternatively, it may be performed immediately after performing PECVD deposition of one or more layers of the layered structure. Alternatively, it may be performed immediately after performing PVD deposition of one or more layers of the layered structure. Alternatively, it may be performed after metallization of the layered structure.

As set out above, step (f) of performing a carrier injection treatment on at least a cut edge of the cell is performed at any time after both of steps (b) and (e) have been performed; that is, after front and back amorphous silicon (a-Si) layers have been deposited on a front side and a back side of the crystalline silicon wafer respectively, and after the cell (or part-manufactured cell) has been cut. This is necessary as the mechanism for defect repair involves the a-Si and c-Si interface. Accordingly, the a-Si layer(s) must have been deposited on the c-Si wafer prior to performing the carrier injection treatment.

In preferred arrangements, the step (f) of performing a carrier injection treatment on at least a cut edge of the cell is performed after each of steps (a)-(d) have been performed. This may allow for improved passivation of all interfaces within the solar cell-including the a-Si-c-Si interface, a-Si/TCO interface and TCO/electrode interface. The step (f) may be the last step in the solar cell manufacturing process.

The step (f) of performing a carrier injection treatment includes a step of performing at least one treatment selected from a light-based carrier injection treatment, or a charge-based carrier injection treatment, for example one or more of a halogen lamp treatment, an LED lamp treatment, an electron injection treatment, and/or a laser treatment. Further optional features of the carrier injection treatment are discussed above in relation to the first aspect of the invention: these apply equally to this aspect of the invention.

In a third aspect, the present invention provides a cut solar cell having been subjected to the method of treatment of the first aspect of the invention, or manufactured according to the method of manufacture of the second aspect of the invention.

The solar cell may be evaluated by one or more performance metrics, including but not limited to photoluminescent intensity (PL intensity). A solar cell according to the present invention may demonstrate an improvement in PL intensity as compared with a module comprising cells not according to the present invention.

The cut solar cell of the third aspect may be incorporated in a solar cell module. Accordingly, in a fourth aspect there is provided a solar module comprising a plurality of solar cells, each according to the third aspect. The solar module may include at least a first and a second solar cell according to the third aspect of the invention. Preferably the solar module includes: at least a first and a second solar cell according to the third aspect of the invention, an outer casing arranged to overlay the first and second solar cells, and an encapsulant interposed between the outer casing and the first and second solar cells.

The first and second solar cells may be electrically coupled to one another. The solar module may comprise a plurality of solar cells. Where the solar module comprises a plurality of solar cells, these may be arranged in an array. The array of solar cells may be arranged in an array which extends in a longitudinal (e.g. lengthwise) and/or a transverse (e.g. widthways) direction of the solar module. The solar cells may be arranged in a grid formation, such as a rectangular or square grid pattern.

Where more than one solar cell is present, some or all of the solar cells may be arranged in substantially the same plane. Accordingly, the solar cells may be arranged in a substantially planar array. The solar cells may each be arranged so that they are aligned within the same reference plane. For example, a first solar cell may be arranged, e.g. orientated, such that a horizontal plane of the first solar cell is aligned with a horizontal plane of a second solar cell. The reference plane of the first and second solar cells may be substantially aligned (e.g. parallel) with a horizontal plane of the solar module. Alternatively, some or all of the solar cells may be arranged in a shingling or shingled arrangement. As such, a first solar cell may be arranged to at least partially overlap a second solar cell.

Typically, the one or more solar cells within the module are electrically connected in series or in parallel with one another. In some arrangements, all of the solar cells within a module may be connected in series. In other arrangements, a selected number of solar cells may be connected in series as a solar cell string. Multiple solar cell strings may be connected in parallel, via one or more bypass diodes. Multiple possible solar cell arrangements are well-known in the art, and any suitable arrangement may be used in the present module.

The encapsulant may be configured to provide encapsulation of the one or more solar cells. In general, this may be defined as a means of physically protecting the solar cells from external environmental conditions, which may include humidity, moisture, rain and ultraviolet radiation (UV). The encapsulant may also be configured to hold the components of the solar module (e.g. the solar cells) in position within the module. The encapsulant may be configured to protect the solar cells from mechanical stresses such as twisting or bending, and low-energy impacts caused by hail or errant projectiles.

The encapsulant may comprise a front encapsulant layer, and a back encapsulant layer. The front encapsulant layer may be directly or indirectly disposed on a front face side of the solar cells. The back encapsulant layer may be directly or indirectly disposed on a back face side of the solar cells. The front encapsulant layer and the back encapsulant layer may be formed of the same material. Alternatively, the front encapsulant layer and the back encapsulant layer may be formed of different materials. The material of the front and/or back encapsulant layers may be selected from ethylene vinyl acetate (EVA), a polyolefin-elastomer (POE) material, or any other suitable encapsulant material known in the art.

The encapsulant may have a thickness which is significantly smaller than its length and width. The lateral extent of the encapsulant may be substantially the same as the lateral extent of the backsheet of the module.

The outer casing of the solar module may comprise a front sheet, or front plate, arranged on a front side of the solar module, and a back sheet or back plate, arranged on a back side of the solar module. The front sheet may be formed of a transparent material, such as glass. The back sheet may be formed of an insulating material, e.g. a polymeric insulating material such as polyethylene terephthalate (PET).

The solar module may include a frame, or one or more frame elements. The frame may be configured to hold the components of the solar module in place and to provide sealing around the perimeter of the outer casing (e.g. the front and back sheets). Where the solar module comprises a front sheet and a back sheet, the frame may apply a compressive force between the front and back sheet in order to retain the components of the solar module in position, as would be readily understood by the skilled person.

The solar module may be evaluated by one or more performance metrics, including but not limited to short-circuit current (ISC), open-circuit voltage (VOC), fill factor (FF), and power conversion efficiency (PCE). A solar module according to the present invention may demonstrate a higher module V_{oc}, and/or a high module Fill Factor % (FF %) as compared with a module comprising cells not according to the present invention.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### SUMMARY OF THE FIGURES

Embodiments and experiments illustrating the principles of the invention will now be discussed with reference to the accompanying figures in which:

FIG. 1 shows a schematic cross-section through a heterojunction solar cell according to the present invention.

FIGS. 2a-e show graphically a series of possible production process sequences for manufacture of a solar cell according to the present invention.

FIG. 3 shows a box plot of Module Voc (‘maxvolt’) for samples according to the present invention (groups T3B-00246, T3B-00247, T3B-00248, and T3B-00249) in comparison to reference samples (groups T3B-00244, T3B-00245).

FIG. 4 shows a box plot of Module FF % (‘Fillfactormaxval’) for samples according to the present invention (groups T3B-00246, T3B-00247, T3B-00248, and T3B-00249) in comparison to reference samples (groups T3B-00244, T3B-00245).

### DETAILED DESCRIPTION OF THE INVENTION

Aspects and embodiments of the present invention will now be discussed with reference to the accompanying figures. Further aspects and embodiments will be apparent to those skilled in the art. All documents mentioned in this text are incorporated herein by reference.

In the drawings, the relative dimensions of various elements of the solar module are shown schematically and are not to scale. For example, the thickness of sheets, layers, films, etc., are exaggerated for clarity. Furthermore, it will be understood that when an element such as a layer, film, region, or substrate is referred to or shown as being “on” or “adjacent” another element, it can be directly on the other element or intervening elements may also be present. In contrast, when an element is referred to as being “directly on” or “directly adjacent” another element, there are no intervening elements present.

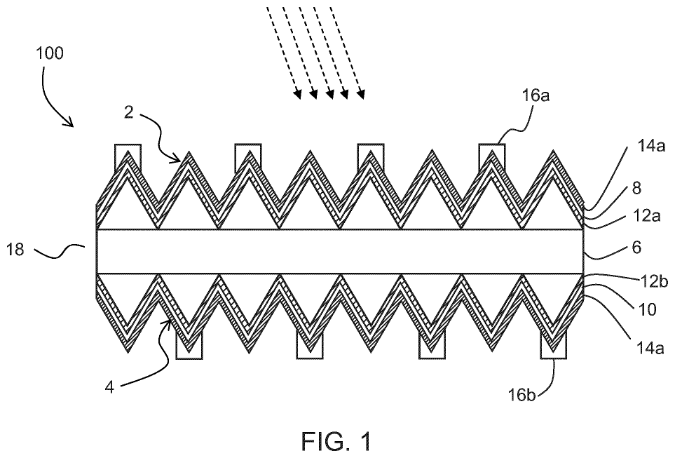

FIG. 1 shows a schematic cross-section through a heterojunction solar cell 100 according to the present invention. The arrows at the top of FIG. 1 show the direction of the solar radiation which is incident upon the solar cell in use. The solar cell has a front surface 2 upon which light is incident in normal use) and a back surface 4 opposite the front surface 2. The front surface is configured in use to substantially face the sun.

The solar cell comprises a layered structure which is generally symmetrical. The ‘base’ of the structure is a crystalline silicon wafer 6, also referred to herein as a c-Si layer or c-Si substrate. The c-Si substrate 6 is formed from an n-type monocrystalline silicon wafer. It is a textured layer.

There is a first collector layer 8 arranged on a front surface of the substrate 6, and a second collector layer 10 arranged on a back surface of the substrate 6. The first collector layer 8 is formed of p-type hydrogenated amorphous silicon (a-Si:H (p)), and so is a hole-collector layer which combines to create a charge separating field at the p-n junction. The second collector layer 10 is formed of n-type amorphous hydrogenated silicon (a-Si:H (n)), and so is an electron-collector layer which is configured to selectively screen, or extract, charge carriers from the substrate 6.

A passivation layer 12a, 12b is arranged between the substrate 6 and each of the first collector layer 8 and second collector layer 10. The passivation layers 12a, 12b are formed of intrinsic amorphous hydrogenated silicon (a-Si).

The solar cell further comprises TCO layers 14a, 14b formed on each of the front and back hydrogenated amorphous silicon (a-Si:H) layers constituted by the passivation & collector layers. These TCO layers are formed from indium tin oxide (ITO). They may provide some anti-reflection functionality.

The solar cell further includes front and back electrodes 16a, 16b, which are formed on the front and back TCO layers, respectively, and which are configured to extract photo-generated charge carriers from the solar cell 100.

At least one edge of the solar cell is a cut edge 18-that is, an edge that has been formed during a cutting process during manufacture of the solar cell. During manufacture, this cut edge is subjected to a treatment process including a carrier injection step.

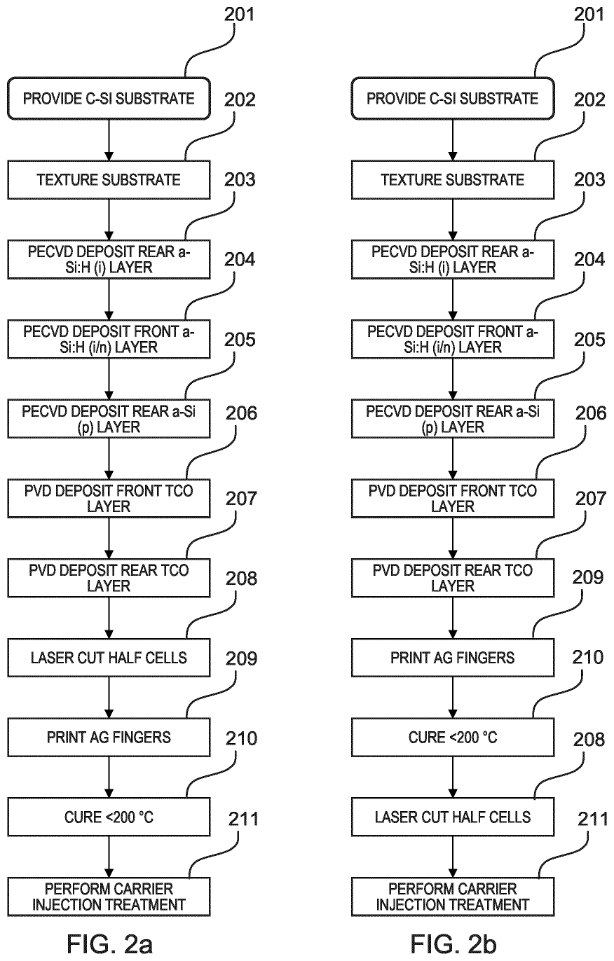

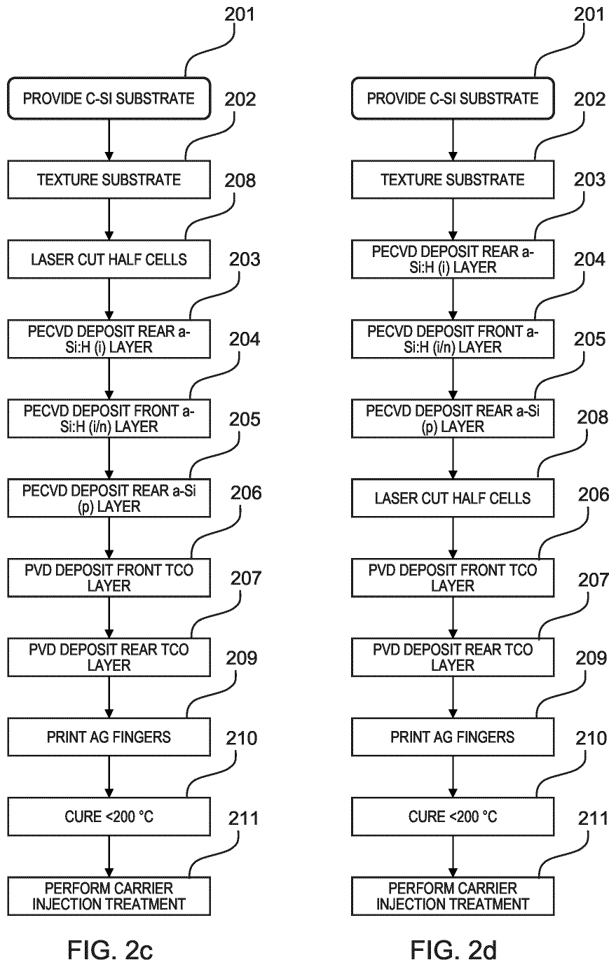

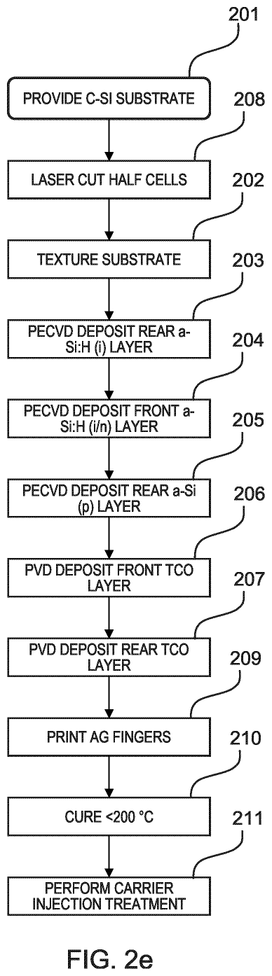

A series of manufacturing methods according the present invention will now be discussed, in relation to FIGS. 2a-e which show graphically a series of possible production process sequences for manufacture of a solar cell according to the present invention.

Each of these production processes includes the following steps in various orders:
Providing a c-Si substrate (step 201)
Texturing the c-Si substrate (step 202) (NB: in some methods, it may not be necessary to perform a texturing step. For example, the c-Si substrate may be provided as a pre-textured substrate. This step is therefore optional)
PECVD depositing front and back hydrogenated amorphous silicon (a-Si:H) layers on a front side and a back side of the crystalline silicon wafer respectively, including sub-steps of:
   PECVD depositing rear a-Si:H (i) layer (step 203)
   PECVD depositing front a-Si:H (i/n) layer (step 204)
   PECVD depositing rear a-Si:H (p) layer (step (205)
depositing front and back transparent conducting oxide (TCO) layers on the front and back hydrogenated amorphous silicon (a-Si:H) layers respectively including sub-steps of:
   PVD deposit front TCO layer (step 206)
   PVD deposit rear TCO layer (step 207)
Laser cut half cells (step 208)
performing metallization to form one or more metal electrodes on the front and/or back TCO layers including sub-steps of:
   Printing Ag fingers (step 209)
   Curing the layered structure at <250° C. (step 210)
Performing carrier injection treatment (step 211)

As can be seen from these process sequences, the step of cutting the solar cell is performed at any time from after provision of the c-Si substrate (step 201), to after the step of performing metallization to form one or more metal electrodes on the front and/or back TCO layers (steps 209, 210).

The step of performing a carrier injection treatment is performed at any time after PECVD depositing front and back hydrogenated amorphous silicon (a-Si:H) layers on a front side and a back side of the crystalline silicon wafer respectively (steps 203, 204, 205), and after cutting of the cell (step 208) has been performed, but preferably it is performed as the final step in the production process, as shown in each of FIG. 2a-e.

Some experimental examples and results will now be discussed.

### Effect of Carrier Injection Treatment on Measured Photoluminescent Intensity (PL Intensity).

A number of samples (12) were treated according to a method of the present invention, to investigate the effect of treatment on measured photoluminescent intensity. Specifically, these samples underwent a charge-based carrier injection treatment. Samples 1-12 that had previously been subjected to a cutting process (i.e. half cut cells) were treated, and compared with reference samples 13 and 14, which had not been previously subjected to a cutting process.

The treatment was performed as follows:
A plurality of cells were stacked together in a coinstack and loaded in a magazine. The cells were stacked in series, negative side of one cell is in contact with positive side of the adjacent cell, vice versa. The magazine was then treated using a charge-based carrier injection process, using an electron injection machine (Changzhou Shichuang Energy Co Ltd. Model: Anti-LID 6000), comprising up to 8 process units.

The cells stack was sandwiched between two metal plates in the magazine and the whole block is lifted up by the bottom electrode in each process unit, after which the top electrode contacted the block to form a complete circuit. A voltage was then applied by the power supply unit in each process unit, causing current to flow through. The amount of current was chosen as a parameter—see tables below for details of applied current selected.

A setpoint temperature was also chosen for each treatment, indicated in the table below, which is a temperature at which the cells are maintained during the treatment. The maintenance of this temperature was achieved by detecting the temperature of the cells using an infrared thermometer, and actuating delivery of compressed dry air (CDA) to the cells as a cooling mechanism when it was detected that the cells were at a temperature higher than the setpoint temperature. In this way, the temperature of the cells could be maintained substantially constantly at the setpoint temperature throughout treatment.

The samples 1-12 were split into 4 groups of three samples each: group G3, G4, G5 and G6. The carrier injection treatment parameters for each group varied, as set out in the table below. Specifically, the treatment duration, treatment temperature, and applied current during treatment were varied.

The photoluminescent intensity of each sample was then measured using a BT Imaging Pty Ltd. Device, Model: LIS-R1. The photoluminescent intensity was determined using the ‘PL open-circuit image measurement’ mode with settings: Exposure time=0.2 s, Illumination area=‘large’, Lightsource setpoint=0.1 suns.

TABLE 1
Data showing change in PL Intensity for various samples and reference samples.

| PL Intensity Value | | | | | | | | | |
|---|---|---|---|---|---|---|---|---|---|
| | | Cell | | | PL | | | | |
| | | sample | Before - | After - | delta | Av. of | Treatment | Temperature | Applied |
| Group | Type | no. | PL mean | PL mean | (A-B) | group | duration | of treatment | current |
| G3 | Half | 1 | 10394.7 | 11496.6 | 1101.9 | 632.3 | 4 × 300 s | 127.5° C. | 5.5/5.8/5.8/5.8 |
| | cells | | | | | | | | A |
| | | 2 | 11213.6 | 12342.1 | 1128.5 | | 4 × 300 s | 127.5° C. | 5.5/5.8/5.8/5.8 |
| | | | | | | | | | A |
| | | 3 | 9385.09 | 9051.6 | −333.5 | | 4 × 300 s | 127.5° C. | 5.5/5.8/5.8/5.8 |
| | | | | | | | | | A |
| G4 | | 4 | 10181.9 | 10254.4 | 72.5 | 273.9 | 4 × 300 s | 142.5° C. | 6/6.7/6.7/6.7 |
| | | | | | | | | | A |
| | | 5 | 8646.01 | 9151.53 | 505.5 | | 4 × 300 s | 142.5° C. | 6/6.7/6.7/6.7 |
| | | | | | | | | | A |
| | | 6 | 9680.9 | 9924.57 | 243.7 | | 4 × 300 s | 142.5° C. | 6/6.7/6.7/6.7 |
| | | | | | | | | | A |
| G5 | | 7 | 13437.6 | 14278.5 | 840.9 | 497.9 | 4 × 300 s | 112.5° C. | 5/5/5/5 A |
| | | 8 | 13128.9 | 13719.4 | 590.5 | | 4 × 300 s | 112.5° C. | 5/5/5/5 A |
| | | 9 | 12233.1 | 12295.4 | 62.3 | | 4 × 300 s | 112.5° C. | 5/5/5/5 A |
| G6 | | 10 | 12645.3 | 13121.9 | 476.6 | −35.7 | 4 × 600 s | 127.5° C. | 4.3/6/6/6 A |
| | | 11 | 9938.81 | 9886.26 | −52.6 | | 4 × 600 s | 127.5° C. | 4.3/6/6/6 A |
| | | 12 | 10043.3 | 9512.21 | −531.1 | | 4 × 600 s | 127.5° C. | 4.3/6/6/6 A |
| Ref | Full | 13 | 13186.6 | 13550.6 | 364 | 258.6 | | | |
| | cells | 14 | 12353.5 | 12506.6 | 153.1 | | | | |

From this data it can be seen that the average increase in PL intensity resulting from the carrier injection treatment of all samples according to the invention (632.3+273.9+497.9−35.7)/4=342.1, was greater than the corresponding increase in PL intensity for the reference samples, 258.6. Whilst no treatment was performed on the full cell samples 13 and 14, a small increase in PL intensity was seen between the first and second measurements. It is hypothesised that this small increase is simply the result of measurement drift over the time for the untreated samples.

It is noted that samples 3, 11 and 12 showed poor performance after treatment: it is hypothesised that these poor results were observed due to possible heat damage during the carrier injection treatment resulting from the stacking arrangement of cells during treatment. Indeed, if these samples are excluded from the results, and the average increase in PL intensity is calculated based on samples 1, 2, 4, 5, 6, 7, 8, 9, and 10 only, the average increase in PL intensity is 558—over twice as large as the corresponding increase in PL intensity for the reference samples.

The greatest increase in PL intensity was seen for samples 1 and 2, which underwent 4 discrete electron injection treatment steps of 300 seconds each, at respective applied currents of 5.5/5.8/5.8/5.8 A, and at a treatment temperature of 127.5° C. These conditions may therefore be preferred treatment conditions for providing an increase in PL Intensity of the solar cells.

### Effect of Carrier Injection Treatment on Module V_{oc} and FF %

The Current—Voltage electrical characteristics of modules incorporating cells treated according to the present invention were also investigated to determine the effect of treatment of the cells on the measured module V_{oc} and FF % of modules incorporating those cells. Test modules were constructed using cells which had experienced the same treatments as samples 1-12. These were compared with comparative test modules constructed using reference cells, which had not been subjected to a cutting process.

The (non-reference) modules tested were split into 4 groups (‘Shoporders’) of three, based on the type of treatment performed on the cells included in each module: T3B-00246, T3B-00247, T3B-00248, and T3B-00249 (see Table 2, below). The carrier injection treatment parameters for each group varied, as set out in the table below. Specifically, the treatment duration, treatment temperature, and applied current during treatment were varied. The reference modules tested are indicated as ‘Shoporders’ T3B-00244 and T3B-00245 (see Table 2, below).

The Module V_{OC} and Module FF % was then measured using a commercially available sun simulator machine for all modules. To measure the Module V_{OC} and Module FF %, probes from the machine are placed in contact with the module contacts. The sun simulator machine then generates a flash of light simulating the sun's emission spectrum received on the Earth's surface. The module will generate electrical current from the light, and the Module V_{OC} and Module FF % are then output by the commercially available sun simulator.

TABLE 2
Data showing module V_{oc} and FF % for test modules constructed using cells which
had experienced the same treatments as samples 1-12 (T3B-00246, T3B-00247, T3B-
00248, and T3B-00249) vs comparative test modules (T3B-00244, T3B-00245).

| | | | | Duration | | |
|---|---|---|---|---|---|---|
| | | | | of | | |
| | | | | treatment | Temperature | |
| | Cell | Av. | Av. | of cells | of treatment | Other parameters of treatment |
| | Type in | Module | Module | in | of cells in | (lumens/current etc.) of cells in |
| Shoporder | module | Voc | FF % | module | module | module |
| T3B- | Half | 43.99 | 79.69 | 4 × 300 s | 127.5° C. | 5.5/5.8/5.8/5.8 A |
| 00246 | cells | | | 4 × 300 s | 127.5° C. | 5.5/5.8/5.8/5.8 A |
| | | | | 4 × 300 s | 127.5° C. | 5.5/5.8/5.8/5.8 A |
| T3B- | | 44.08 | 79.95 | 4 × 300 s | 142.5° C. | 6/6.7/6.7/6.7 A |
| 00247 | | | | 4 × 300 s | 142.5° C. | 6/6.7/6.7/6.7 A |
| | | | | 4 × 300 s | 142.5° C. | 6/6.7/6.7/6.7 A |
| T3B- | | 44.03 | 79.77 | 4 × 300 s | 112.5° C. | 5/5/5/5 A |
| 00248 | | | | 4 × 300 s | 112.5° C. | 5/5/5/5 A |
| | | | | 4 × 300 s | 112.5° C. | 5/5/5/5 A |
| T3B- | | 44.10 | 80.11 | 4 × 600 s | 127.5° C. | 4.3/6/6/6 A |
| 00249 | | | | 4 × 600 s | 127.5° C. | 4.3/6/6/6 A |
| | | | | 4 × 600 s | 127.5° C. | 4.3/6/6/6 A |
| T3B- | Full | 43.97 | 79.57 | 4 × 300 s | 127.5° C. | 8/8/8/8 A |
| 00244 | cells | | | | | |
| (reference) | | | | | | |
| T3B- | Full | 43.98 | 79.61 | 3 × 300 s | 127.5° C. | 10/6.5/5.2 A |
| 00245 | cells | | | | | |
| (reference) | | | | | | |

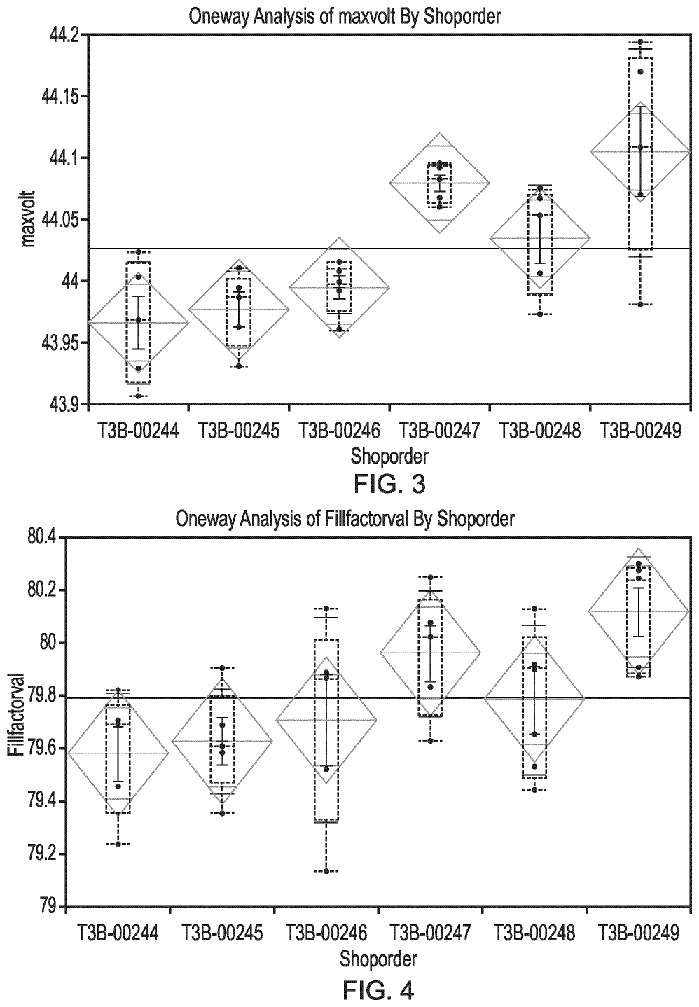

This data is also shown as a series of box plots in FIG. 3 and FIG. 4. It can be seen that the average module V_{oc} and average FF % was better for all module groups where the cells in the modules had previously been subjected to a cutting process (shoporders T3B-00246, T3B-00247, T3B-00248, and T3B-00249) as compared with modules containing cells which had not previously been subjected to a cutting process (shoporders T3B-00244, T3B-00245), indicating again that solar cell treatments according to the present invention result in surprisingly improved technical performance.

Highest average module V_{oc} and FF % were observed for group T3B-00249 which underwent 4 discrete electron injection treatment steps of 600 seconds each, at respective applied currents of 4.3/6/6/6 A, and at a treatment temperature of 127.5° C. These conditions may therefore be preferred treatment conditions for providing an increase in module V_{oc} and FF % of modules incorporating solar cells according to the present invention.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example+/−10%.

1. A method of treatment of at least one cut solar cell, the method including steps of:
providing the at least one solar cell, said cell having previously been subjected to a cutting process; and
performing a carrier injection treatment on at least a cut edge of the cell.

2. The method according to claim 1 wherein the solar cell is a heterojunction solar cell.

3. The method according to claim 1, wherein the carrier injection treatment includes at least one treatment selected from: a light-based carrier injection treatment, or a charge-based carrier injection treatment.

4. The method according to claim 3 wherein the carrier injection treatment is a light-based carrier injection treatment selected from:
i. a halogen lamp treatment comprising a step of exposing at least the cut edge of the cell to light emitted from a halogen lamp having a luminous flux (lm) in a range of from 10000 lm to 60000 lm;
ii. an LED lamp treatment comprising a step of exposing at least the cut edge of the cell to light emitted from an LED lamp at a light intensity of from 80 to 180 suns, wherein 1 sun corresponds to standard illumination at AM1.5; and/or
iii. a laser treatment comprising a step of exposing at least the cut edge of the cell to light emitted from a laser having a specified predetermined wavelength and a power in the range of from 1000-4000 W.

5. The method according to claim 3, wherein the carrier injection treatment is a light-based carrier injection treatment and wherein the distance between the cell(s) being treated and a light source used in the treatment is in a range of from 5 to 40 cm.

6. The method according to claim 3 wherein the carrier injection treatment includes a charge-based carrier injection treatment, including a step of applying a voltage to the at least one cut solar cell, causing a current to flow through.

7. The method according to claim 6 wherein the charge-based carrier injection treatment is performed at an applied current of from 4 to 10 A.

8. The method according to claim 1, wherein the carrier injection treatment comprises a plurality of discrete carrier injection treatment steps.

9. The method according to claim 8 wherein one or more parameters of the carrier injection treatment are varied between the discrete carrier injection treatment steps.

10. The method according to claim 1, wherein the treatment is performed for a total time of between 5 seconds and 1 hour.

11. The method according claim 1, wherein the carrier injection treatment is performed such that the cell temperature is in a range of from 100° C. to 300° C. during the carrier injection treatment.

12. The method according to claim 1 wherein a plurality of cut solar cells are treated simultaneously.

13. A method of manufacture of a solar cell, the method including steps of:
(a) providing a crystalline silicon (c-Si) wafer;
(b) depositing front and back amorphous silicon (a-Si) layers on a front side and a back side of the crystalline silicon wafer respectively;
(c) depositing front and back transparent conducting oxide (TCO) layers on the front and back amorphous silicon (a-Si) layers respectively;
(d) performing metallization to form one or more metal electrodes on the front and/or back TCO layers;
(e) cutting the solar cell; and
(f) performing a carrier injection treatment on at least a cut edge of the cell;
wherein the step (e) of cutting the solar cell is performed at any time from after step (a) to after step (d), and wherein step (f) of performing a carrier injection treatment on at least a cut edge of the cell is performed at any time after both of steps (b) and (e) have been performed.

14. The method according to claim 13 wherein step (f) of performing a carrier injection treatment on at least a cut edge of the cell is performed after each of steps (a)-(d) have been performed.

15. The method according to claim 13, wherein the carrier injection treatment includes at least one treatment selected from a light-based carrier injection treatment, or a charge-based carrier injection treatment.

16. The method according to claim 13, wherein the step (b) of depositing front and back amorphous silicon (a-Si) layers on a front side and a back side of the crystalline silicon wafer respectively includes sub-steps of:
(i) depositing a front and back intrinsic amorphous silicon (a-Si (i)) layer on a front side and a back side of the crystalline silicon wafer respectively; and
(ii) depositing a p- or n-doped hydrogenated amorphous silicon (a-Si (n), a-Si (p)) layer on each of the front and back intrinsic amorphous silicon (a-Si (i)) layers.

17. The method according to claim 13, wherein the step (b) of depositing front and back amorphous silicon (a-Si) layers on a front side and a back side of the crystalline silicon wafer respectively is performed using plasma-enhanced chemical vapor deposition (PECVD).

18. The method according to claim 13, wherein the step (c) of depositing front and back transparent conducting oxide (TCO) layers on the front and back amorphous silicon (a-Si) layers respectively is performed using physical vapor deposition (PVD).

19. The method according to claim 13, wherein the step (d) of performing metallization to form one or more metal electrodes on the front and/or back TCO layers comprises sub-steps of applying a metallisation material to the front and/or back TCO layers and performing a heat treatment to form the one or more metal electrodes from the metallisation material.

20. The method according to claim 13, wherein the step (e) of cutting the solar cell is performed by a laser-based or laser-assisted cutting process.

21. A cut solar cell having been subjected to the method of treatment of claim 1.
